(19) United States
(12) Patent Application Publication
(10) Pub. No.: US 2006/0164070 A1
(43) Pub. Date: Jul. 27, 2006

(54) Method and device for voltage measurement of an ac power supply

(76) Inventor: Artur Wilhelm Suntken, Pretoria (ZA)

Correspondence Address: BAKER & BOTTS, 30 ROCKEFELLER PLAZA, 44TH FLOOR, NEW YORK, NY, 10112, US

(21) Appl. No.: 10/522,348

(22) PCT Filed: Jul. 23, 2003
(86) PCT No.: PCT/IB03/02915

§ 371 Date: Jul. 27, 2005

(30) Foreign Application Priority Data
Jul. 23, 2002 (ZA) 2002/5873

(51) Int. Cl. G01R 11/32

(52) U.S. Cl. 324/142

(57) ABSTRACT

In an electronic device having an electrical circuit connected to live and neutral lines of an AC power supply via a bridge rectifier for the provision of DC power, a method for ascertaining the AC power supply voltage includes providing a corrected voltage signal comprising a differential between signals representative of the live and neutral AC voltage signals, each signal referenced to a preselected common voltage reference point in the circuit of the device. The invention extends to a voltage ascertaining means for use in such an electronic device.

### FIELD OF THE INVENTION

This invention relates to electronics. More particularly, the invention relates to the ascertaining of voltage. In particular, the invention relates to a method and a means for ascertaining voltage. In a specific embodiment, the invention relates to a power supply and to a method for compensating for an error in a power supply, more particularly a bridge power supply. The invention has particular application in the field of metering.

### BACKGROUND TO THE INVENTION

The use of bridge rectifier circuits in power supplies is well known. A common full wave bridge rectifier power supply has a quartet of diodes arranged in circuit to provide a rectifier stage of the power supply. The use of a bridge rectifier circuit provides a full wave rectifier, which does not generally require the use of a transformer. The bridge rectifier further permits the size of a voltage dropping capacitor, which is commonly used in the input stage of such power supplies, to be reduced to about half the capacitance of a corresponding capacitor in a non-bridge rectifier circuit, thereby reducing power consumption in the power supply circuit. However, the use of bridge rectifier circuits may introduce errors in the measurement of the AC input voltage to the bridge rectifier. This is particularly important where the power supply is used to provide power for an electricity consumption meter, which is, in turn, used to measure the input line voltage to the power supply, i.e. the voltage between the live and neutral conductors of an AC electricity reticulation circuit. Voltage errors in the voltage measurements of such meters originate largely as a result of the fact that there is no stable reference voltage, with respect to which the live voltage to be measured may be referenced, since the meter generally has a floating earth providing a reference for voltage measurements. The error introduced in the measurement due to the bridge rectifier circuit generally takes the form of a small error in phase and amplitude and is time dependant. Furthermore, the size of the error is somewhat unpredictable and depends partly on the DC voltage level of the bridge output.

### OBJECT OF THE INVENTION

It is an object of this invention to provide a method and means for ascertaining voltage for use, particularly, but not exclusively, in the metering of electrical power, which will, at least partially, alleviate some of the abovementioned problems.

### SUMMARY OF THE INVENTION

According to a first aspect of the invention there is provided, in an electronic device having an electrical circuit connected to live and neutral lines of an AC power supply via a bridge rectifier for the provision of DC power to the circuit, a method for ascertaining the AC power supply voltage, the method including providing a corrected voltage signal comprising a differential between signals representative of the live and neutral AC voltage signals, each signal referenced to a preselected common voltage reference point in the circuit of the device.

The reference point may be a floating earth point of the circuit and the method may include the steps of

providing a first neutral error voltage signal representative of the voltage signal of the neutral line of the AC power supply with reference to the floating earth of the circuit;

providing a second live error voltage signal representative of the voltage signal of the live line of the AC power supply with reference to the floating earth of the circuit; and

subtracting the first error voltage signal from the second error voltage signal to provide the corrected voltage signal.

Instead of the subtraction step, the method may include the steps of

inverting the first error voltage signal; and

adding the inverted signal to the second error voltage signal to provide the corrected voltage signal.

The step of inverting the first error voltage signal may be by means of an inverter. Then, the inverter may comprise an amplifier with an amplification of minus one.

The bridge rectifier may have a bridge rectifier circuit having first and second input nodes for connection respectively to live and neutral lines of the AC power supply and has positive and negative DC output nodes for connection to a load, and the step of inverting the first error voltage signal may comprise inverting the voltage signal measured between a neutral input node of the rectifier bridge circuit and the floating earth point of the device driven by the power supply (the neutral error voltage); and the step of adding the inverted signal to the second error voltage signal to provide the corrected voltage signal may comprise adding the inverted signal to the voltage signal measured between the live AC line and the floating earth of the device (the live error voltage).

The device may be an electricity consumption meter (power meter). In one embodiment of the invention, the power meter is a current transformer meter.

According to a second aspect of the invention there is provided, in an electronic device having an electrical circuit connected to live and neutral lines of an AC power supply via a bridge rectifier for the provision of DC power to the circuit, a voltage ascertaining means operable to provide a voltage signal comprising a differential between voltage signals representative of the live and neutral AC voltage signals, each signal referenced to a preselected common voltage reference point in the circuit of the device.

The bridge rectifier may include a bridge rectifier circuit having first and second input nodes for connection respectively to live and neutral lines of an AC power supply and having positive and negative DC output nodes for connection to a load and the voltage ascertaining means may include an error compensation circuit operably connected to the bridge rectifier circuit.

The error compensation circuit may include

means for providing a first neutral error voltage signal representative of the voltage signal of the neutral line of the AC power supply with reference to the floating earth of the circuit;

means for providing a second live error voltage signal representative of the voltage signal of the live line of the AC power supply with reference to the floating earth of the circuit; and

subtraction means for subtracting the first error voltage signal from the second error voltage signal to provide the corrected voltage signal.

Instead of subtraction means, the error compensation circuit may include

inverting means for inverting the first error voltage signal; and

addition means for adding the inverted signal to the second error voltage signal to provide the corrected voltage signal.

The inverting means may comprise an amplifier having an amplification of minus one.

The inverter may be operable to invert the voltage signal measured between a neutral input node of the rectifier bridge circuit and the floating earth point of the device driven by the power supply (the neutral error voltage) and to add the inverted signal to the voltage signal measured between the live AC line and the floating earth of the device (the live error voltage).

The error compensation circuit may be operably connected to a power supply for providing power to an energy consumption meter (power meter) for the measurement of power use from an AC power source, such as a utility reticulation circuit, the energy meter providing the load for the power supply and being connected to the output nodes of the bridge rectifier circuit via the error compensation circuit; and the energy meter may have a floating earth providing a reference for measuring the voltage of the AC signal to be metered, the error compensation circuit compensating for an error in the AC voltage signal measured by the meter by adding an inverted error compensating signal to the voltage signal measured by the meter between its floating earth and the live line of the AC power supply. It will be appreciated that this will result in the elimination or reduction of the error in the voltage signal measured by the meter between its floating earth and the live line of the AC power supply.

Instead, the error compensation circuit may be operably connected to a power supply for providing power to an energy consumption meter (power meter) for the measurement of power use from an AC power source, the energy meter providing the load for the power supply and being connected to the output nodes of the bridge rectifier circuit via the error compensation circuit; and the energy meter may have a floating earth providing a reference for measuring the voltage of the AC signal to be metered, the error compensation circuit compensating for an error in the AC voltage signal measured by the meter by subtracting the error compensating signal from the voltage signal measured by the meter between its floating earth and the live line of the AC power supply. It will again be appreciated that this will result in the elimination or reduction of the error in the voltage signal measured by the meter between its floating earth and the live line of the AC power supply.

Again, the electricity consumption meter (power meter) may be a current transformer meter.

Those familiar with power metering will appreciate that the voltage in the measurement circuit may be stepped down from the AC input voltage, so that the signal measured by the meter bears a known relationship to, and is representative of, the AC live voltage. Similarly, the error compensating voltage may be stepped down correspondingly.

The invention extends to a bridge power supply incorporating a voltage ascertaining means as hereinbefore described.

### BRIEF DESCRIPTION OF THE DRAWINGS

The invention is now described below, by way of example only, and with reference to the accompanying drawings in which:

FIG. 1 shows a block diagram illustrating a method for ascertaining an AC voltage, in accordance with the invention;

FIG. 2 shows a block diagram of an alternative embodiment of the method of the invention;

FIG. 3 shows a circuit diagram of a general form of a DC bridge power supply in accordance with the invention;

FIG. 4 shows a circuit diagram of an embodiment of the DC bridge power supply; and

FIG. 5 shows a series of voltage signal traces measured at various points of the power supply of FIG. 4.

### DETAILED DESCRIPTION OF THE INVENTION

In the drawings, reference numeral 1 generally refers to a voltage ascertaining means, in accordance with an aspect of the invention.

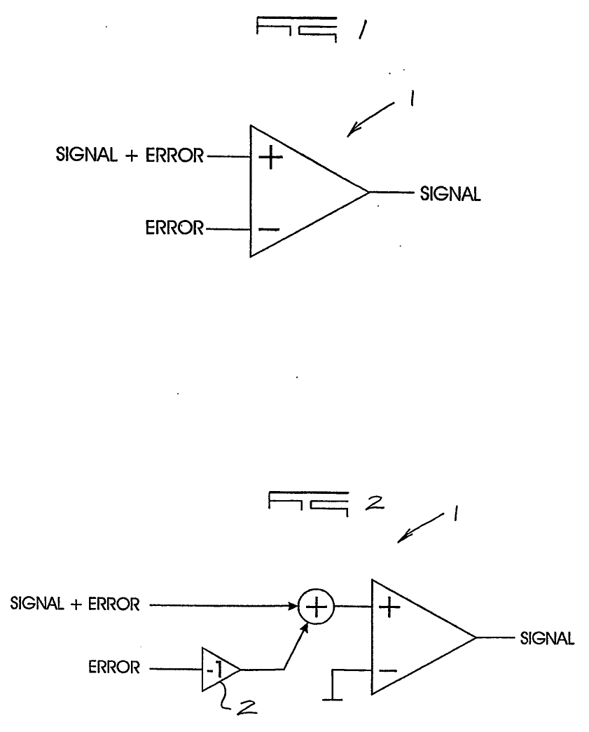

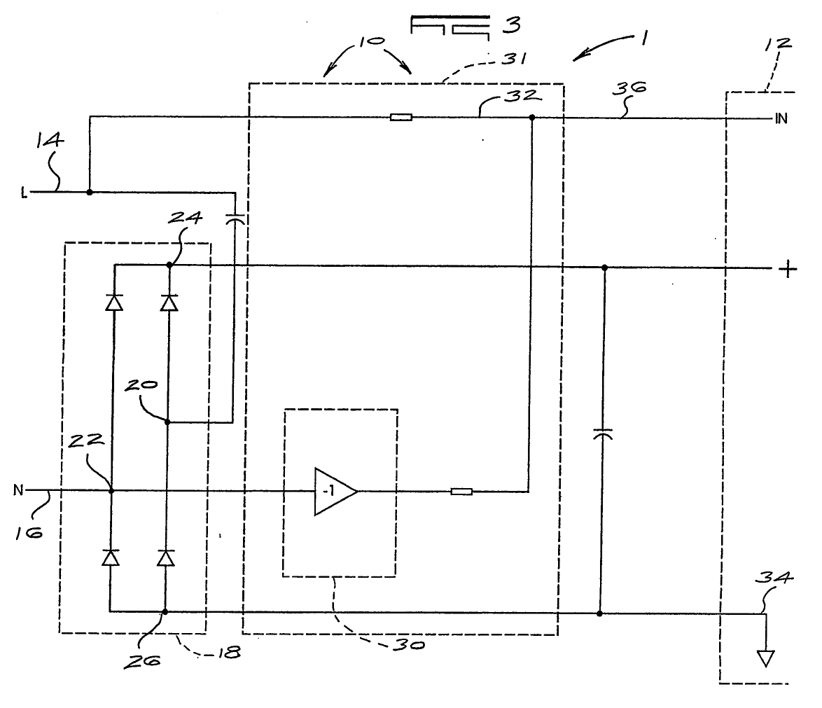

In FIGS. 1 and 2, the form of the circuit of the voltage ascertaining means is not shown. In FIG. 1, the means 1 is operable to subtract an error voltage signal from a voltage signal containing a voltage error to provide a corrected voltage signal for use or measurement by an unspecified device. In FIG. 2, the voltage error signal is inverted by means of an amplifier 2 having an amplification of minus one and the inverted error signal added to the voltage signal containing the voltage error, to provide the corrected voltage signal.

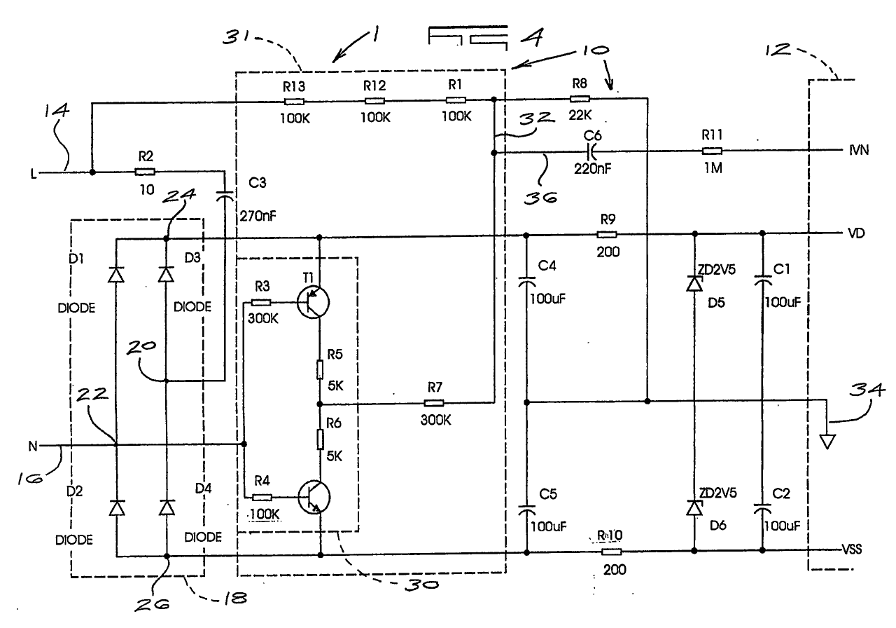

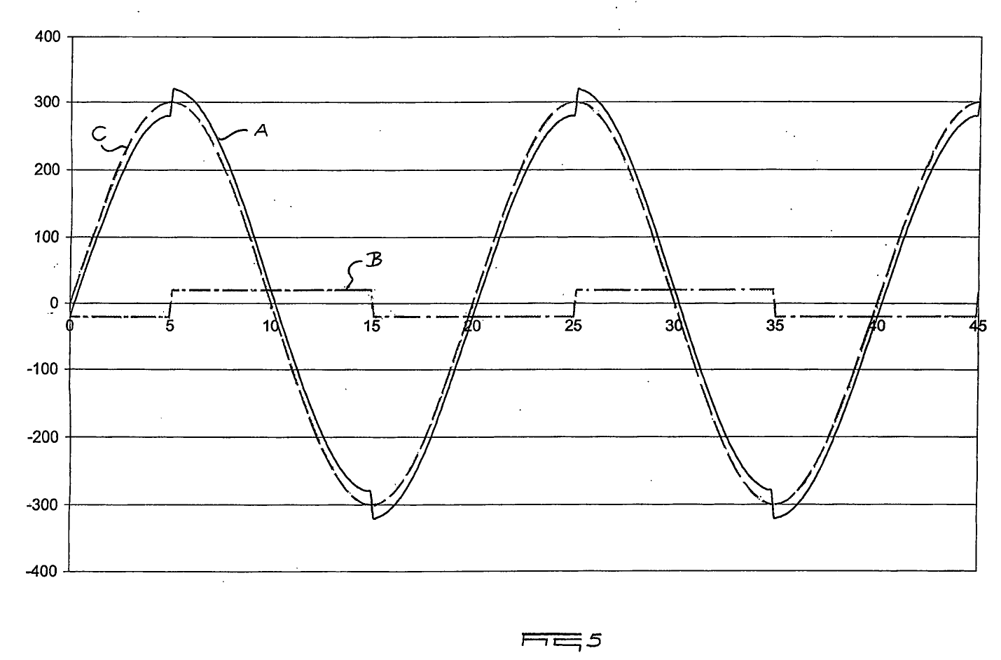

In FIGS. 3 and 4, reference numeral 10 generally refers to a circuit for a DC bridge power supply in accordance with the invention.

The power supply circuit 10 is shown connected to a power meter 12 (details of which are omitted) for metering electricity consumption from an electricity reticulation circuit having live and neutral lines 14 and 16, respectively.

The power supply circuit 10 has a full wave bridge rectifier circuit 18. The bridge rectifier circuit 18 has first and second input nodes 20,22, which are connected respectively to the live and neutral input lines 14,16 of the AC power supply (the reticulation circuit). Further, the bridge rectifier circuit 18 has positive and negative output nodes 24 and 26 respectively, which are connected to a load, being generally the power meter 12 driven by the DC bridge power supply 10, via an intermediate stage of the power supply circuit 10.

The power supply circuit 10 has an error compensation circuit 30 operatively connected to the second input node 22 of the bridge rectifier circuit 18. The error compensation circuit 30 forms part of a voltage ascertaining circuit 31, being an embodiment of the voltage ascertaining means of the invention. The circuit 31 provides a voltage signal, at 36, comprising a differential between voltage signals representative of the live and neutral AC voltage signals of the lines 14,16. Each of the voltage signals is referenced to a preselected common voltage reference point in the circuit of the device, in this case the floating earth point 34 of the power meter 12.

The error compensation circuit 30 detects the so called neutral error by detecting the voltage signal measured between the neutral input node 22 of the bridge rectifier circuit 18 and a floating earth 34 of the power meter 12. The compensating error correction signal is provided by inverting the detected error signal. It will be appreciated that the power meter 12 has a floating earth 34 providing a reference for measuring the voltage of the AC signal to be metered.

The error compensation circuit 30 comprises an inverter, which may be an amplifier having an amplification of minus one, as shown in the embodiment shown in FIG. 4. Then, it will be appreciated that the addition of the compensating error correction signal to the live line 32 from the AC power supply will result in the elimination or reduction of the error in the voltage signal measured by the meter 12 between its floating earth 34 and the live line of the AC power supply (measured in a branch 36 of the circuit 10 after the introduction of the compensating voltage). It will be further appreciated that both the AC voltage being measured and the compensating error correction signal are stepped down by the use of suitable resistors in the circuit 31. In an alternative embodiment of the invention, the error compensation circuit 30 may be replaced by a suitable device for subtracting the neutral voltage error directly from the AC voltage to be measured, obviating the need for an inverter.

FIG. 5 shows various voltage signal traces with reference to the power supply circuit 10 of FIG. 4. In FIG. 5, a trace of the voltage signal between the floating earth point 34 of the meter 12 and the live line of the AC power supply before correction, as at 32 (live line of the AC power supply), is indicated by reference letter “A” in FIG. 5. The trace is basically sinusoidal with a superimposed error having the effect of a small amplitude and phase shift in the sinusoidal wave form. The error is measured between the floating earth point 34 of the meter 12 and the neutral input node 22 of the rectifier bridge circuit 18 (neutral line 16 of the AC power supply). The wave form of the neutral error voltage is a time-dependant wave which is approximately 90° out of phase with the voltage signal A and is indicated by reference letter “B” in FIG. 5. Finally, the trace indicated by reference letter “C” in FIG. 5, shows the voltage wave form resulting from the inversion of the error voltage signal B and the addition thereof to the wave form A. The resultant voltage signal C is generally sinusoidal in form and has an amplitude approximately equal to that of the AC signal of the reticulation circuit (after taking account of voltage drops through relevant voltage reducing resistors in the circuit 10).

By means of the invention there is provided method and means for ascertaining a voltage, and a power supply which makes use of a DC rectifier bridge and corrects for errors or distortions introduced by the rectifier bridge. This permits the accurate metering of electricity usage by means of a power meter supplied with DC power by the power supply. The meter may more accurately meter the input AC supply voltage, notwithstanding that it uses as a reference its own floating earth for the purposes of voltage measurement.

1-20. (canceled)

21. In an electronic device having an electrical circuit connected to live and neutral lines of an AC power supply via a bridge rectifier for the provision of DC power to the circuit, a method for ascertaining the AC power supply voltage, the method including providing a corrected voltage signal comprising a differential between signals representative of the live and neutral AC voltage signals, each signal referenced to a preselected common voltage reference point in the circuit of the device.

22. The method of claimed in claim 21, in which the reference point is a floating earth point of the circuit and the method includes the steps of providing a first neutral error voltage signal representative of the voltage signal of the neutral line of the AC power supply with reference to the floating earth of the circuit, further comprising the steps of:
providing a second live error voltage signal representative of the voltage signal of the live line of the AC power supply with reference to the floating earth of the circuit; and
subtracting the first error voltage signal from the second error voltage signal to provide the corrected voltage signal.

23. The method of claim 21, in which the reference point is a floating earth point of the circuit and the method includes the steps of providing a first neutral error voltage signal representative of the voltage signal of the neutral line of the AC power supply with reference to the floating earth of the circuit, further comprising the steps of:
providing a second live error voltage signal representative of the voltage signal of the live line of the AC power supply with reference to the floating earth of the circuit;
inverting the first error voltage signal; and
adding the inverted signal to the second error voltage signal to provide the corrected voltage signal.

24. The method of claim 23, in which the step of inverting the first error voltage signal is by means of an inverter.

25. The method of claim 24, in which the inverter comprises an amplifier with an amplification of minus one.

26. The method of claim 24, in which the bridge rectifier has a bridge rectifier circuit having first and second input nodes for connection respectively to live and neutral lines of the AC power supply and has positive and negative DC output nodes for connection to a load, and in which the step of inverting the first error voltage signal comprises inverting the voltage signal measured between a neutral input node of the rectifier bridge circuit and the floating earth point of the device driven by the power supply (the neutral error voltage); and the step of adding the inverted signal to the second error voltage signal to provide the corrected voltage signal comprises adding the inverted signal to the voltage signal measured between the live AC line and the floating earth of the device (the live error voltage).

27. The method of claim 25, in which the bridge rectifier has a bridge rectifier circuit having first and second input nodes for connection respectively to live and neutral lines of the AC power supply and has positive and negative DC output nodes for connection to a load, and in which the step of inverting the first error voltage signal comprises inverting the voltage signal measured between a neutral input node of the rectifier bridge circuit and the floating earth point of the device driven by the power supply (the neutral error voltage); and the step of adding the inverted signal to the second error voltage signal to provide the corrected voltage signal comprises adding the inverted signal to the voltage signal measured between the live AC line and the floating earth of the device (the live error voltage).

28. The method of claim 21, in which the device is an electricity consumption meter (power meter).

29. The method of claim 28, in which the power meter is a current transformer meter.

30. In an electronic device having an electrical circuit connected to live and neutral lines of an AC power supply via a bridge rectifier for the provision of DC power to the circuit, a voltage ascertaining means operable to provide a voltage signal comprising a differential between voltage signals representative of the live and neutral AC voltage signals, each signal referenced to a preselected common voltage reference point in the circuit of the device.

31. The voltage ascertaining means of claim 30, in which the bridge rectifier includes a bridge rectifier circuit having first and second input nodes for connection respectively to live and neutral lines of an AC power supply and having positive and negative DC output nodes for connection to a load and in which the voltage ascertaining means includes an error compensation circuit operably connected to the bridge rectifier circuit.

32. The voltage ascertaining means of claim 31, in which the error compensation circuit includes means for providing a first neutral error voltage signal representative of the voltage signal of the neutral line of the AC power supply with reference to the floating earth of the circuit; means for providing a second live error voltage signal representative of the voltage signal of the live line of the AC power supply with reference to the floating earth of the circuit; and subtraction means for subtracting the first error voltage signal from the second error voltage signal to provide the corrected voltage signal.

33. The voltage ascertaining means of claim 31, in which the error compensation circuit includes means for providing a first neutral error voltage signal representative of the voltage signal of the neutral line of the AC power supply with reference to the floating earth of the circuit; means for providing a second live error voltage signal representative of the voltage signal of the live line of the AC power supply with reference to the floating earth of the circuit; inverting means for inverting the first error voltage signal; and addition means for adding the inverted signal to the second error voltage signal to provide the corrected voltage signal.

34. The voltage ascertaining means of claim 33, in which the inverting means comprises an amplifier having an amplification of minus one.

35. The voltage ascertaining means of claim 34, in which the inverter is operable to invert the voltage signal measured between a neutral input node of the rectifier bridge circuit and the floating earth point of the device driven by the power supply (the neutral error voltage) and to add the inverted signal to the voltage signal measured between the live AC line and the floating earth of the device (the live error voltage).

36. The voltage ascertaining means of claim 35, in which the error compensation circuit is operably connected to a power supply for providing power to an energy consumption meter (power meter) for the measurement of power use from an AC power source, the energy meter providing the load for the power supply and being connected to the output nodes of the bridge rectifier circuit via the error compensation circuit; and the energy meter has a floating earth providing a reference for measuring the voltage of the AC signal to be metered, the error compensation circuit compensating for an error in the AC voltage signal measured by the meter by adding an inverted error compensating signal to the voltage signal measured by the meter between its floating earth and the live line of the AC power supply.

37. The voltage ascertaining means as claimed in claim 32, in which the error compensation circuit is operably connected to a power supply for providing power to an energy consumption meter (power meter) for the measurement of power use from an AC power source, the energy meter providing the load for the power supply and being connected to the output nodes of the bridge rectifier circuit via the error compensation circuit; and the energy meter has a floating earth providing a reference for measuring the voltage of the AC signal to be metered, the error compensation circuit compensating for an error in the AC voltage signal measured by the meter by subtracting the error compensating signal from the voltage signal measured by the meter between its floating earth and the live line of the AC power supply.

38. The voltage ascertaining means of claim 36, in which the electricity consumption meter (power meter) is a current transformer meter.

39. The voltage ascertaining means of claim 37, in which the electricity consumption meter (power meter) is a current transformer meter.

40. A bridge power supply incorporating a voltage ascertaining means as claimed claim 31.

41. In an electronic device having an electrical circuit connected to live and neutral lines of an AC power supply via a bridge rectifier for the provision of DC power to the circuit, a method for ascertaining the AC power supply voltage substantially as herein described with reference to the accompanying diagrammatic drawings.

42. In an electronic device having an electrical circuit connected to live and neutral lines of an AC power supply via a bridge rectifier for the provision of DC power to the circuit, a voltage ascertaining means substantially as herein described and illustrated with reference to the accompanying diagrammatic drawings.
